(19) United States
(12) Patent Application Publication
(10) Pub. No.: US 2025/0069964 A1
(43) Pub. Date: Feb. 27, 2025

(54) HOUSING, SEMICONDUCTOR MODULE INCLUDING A HOUSING, AND METHOD FOR ASSEMBLING A SEMICONDUCTOR MODULE

(71) Applicant: Infineon Technologies AG, Neubiberg (DE)

(72) Inventors: Marco Ludwig, Wickede/Ruhr, Nordrhein-Westfalen (DE); Roman Lennart Tschirbs, Soest (DE)

(21) Appl. No.: 18/802,657

(22) Filed: Aug. 13, 2024

(30) Foreign Application Priority Data
Aug. 21, 2023 (EP) 23192410

(51) Int. Cl. H01L 23/10; H01L 21/50; H01L 23/04; H01L 23/538; H01L 25/00

(52) U.S. Cl. CPC H01L 23/10; H01L 21/50; H01L 23/041; H01L 23/538; H01L 25/00

(57) ABSTRACT

A housing for a semiconductor module includes a first housing member and a second housing member. In an unmounted state of the housing, the first housing member and the second housing member are separate and distinct from each other. In an assembled state of the housing, the first housing member and the second housing member are attached to each other and together form a closed frame. The closed frame formed by the first housing member and the second housing member includes a mounting section for mounting the housing to a substrate such that the closed frame extends around the substrate.

### TECHNICAL FIELD

The instant disclosure relates to a housing, a semiconductor module comprising a housing, and a method for assembling a semiconductor module.

### BACKGROUND

Power semiconductor module arrangements often include at least one substrate arranged in a housing. A semiconductor arrangement including a plurality of controllable semiconductor elements (e.g., two IGBTs in a half-bridge configuration) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may optionally be attached to a base plate.

The housing may be glued to the substrate. Gluing the housing to the substrate, however, requires pretreatment steps (e.g., a plasma treatment of the substrate), a step in which the glue is applied to the substrate, as well as a hardening step in which the originally viscous glue is hardened, thereby permanently attaching the housing to the substrate. Each additional step during the assembly process requires additional process time and increases the overall cost of the power semiconductor module arrangement.

There is a need for a housing and a power semiconductor module arrangement comprising a housing that may be assembled in an effective and cost-efficient way.

### SUMMARY

A housing for a semiconductor module includes a first housing member and a second housing member, wherein in an unmounted state of the housing, the first housing member and the second housing member are separate and distinct from each other, in an assembled state of the housing, the first housing member and the second housing member are attached to each other and together form a closed frame, and the closed frame formed by the first housing member and the second housing member includes a mounting section for mounting the housing to a substrate such that the closed frame extends around the substrate.

A semiconductor module includes a housing in its assembled shape, and a substrate, wherein the housing forms a closed frame around the substrate and exerts pressure on at least some of a plurality of side surfaces of the substrate along the circumference of the substrate.

A method for assembling a semiconductor module includes arranging a housing to surround a substrate, wherein arranging the housing to surround the substrate includes moving the first housing member (and the second housing member towards each other, with the substrate arranged between the first housing member and the second housing member, and attaching the first housing member to the second housing member such that the first and second housing members together form a closed frame around the substrate and exert pressure on at least some of a plurality of side surfaces of the substrate along the circumference of the substrate.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module in which the housing is glued to the substrate.

FIG. 2 is a cross-sectional view of a semiconductor module comprising a housing according to embodiments of the disclosure.

FIG. 3 is a top view of a semiconductor module comprising a housing according to embodiments of the disclosure, during assembly of the semiconductor module.

FIG. 4 schematically illustrates a cross-sectional view of a section of a semiconductor module according to embodiments of the disclosure.

FIGS. 5A and 5B schematically illustrate a cross-sectional view (FIG. 5A) and a top view (FIG. 5B) of a section of a semiconductor module according to embodiments of the disclosure.

FIGS. 6A and 6B schematically illustrate cross-sectional views of a section of a semiconductor module according to embodiments of the disclosure.

FIG. 7 schematically illustrates a three-dimensional view of a semiconductor module comprising a housing according to embodiments of the disclosure.

FIG. 8 schematically illustrates a top view of a semiconductor module comprising a housing according to embodiments of the disclosure.

FIGS. 9A and 9B schematically illustrate a top view (FIG. 9A) of a semiconductor module and a three-dimensional cross-sectional view (FIG. 9B) of a section of a semiconductor module according to embodiments of the disclosure.

FIG. 10 is a top view of a semiconductor module comprising a housing according to further embodiments of the disclosure, during assembly of the semiconductor module.

FIG. 11 is a top view of a semiconductor module comprising a housing according to even further embodiments of the disclosure, during assembly of the semiconductor module.

FIG. 12 is a top view of a semiconductor module comprising a housing according to even further embodiments of the disclosure, during assembly of the semiconductor module.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

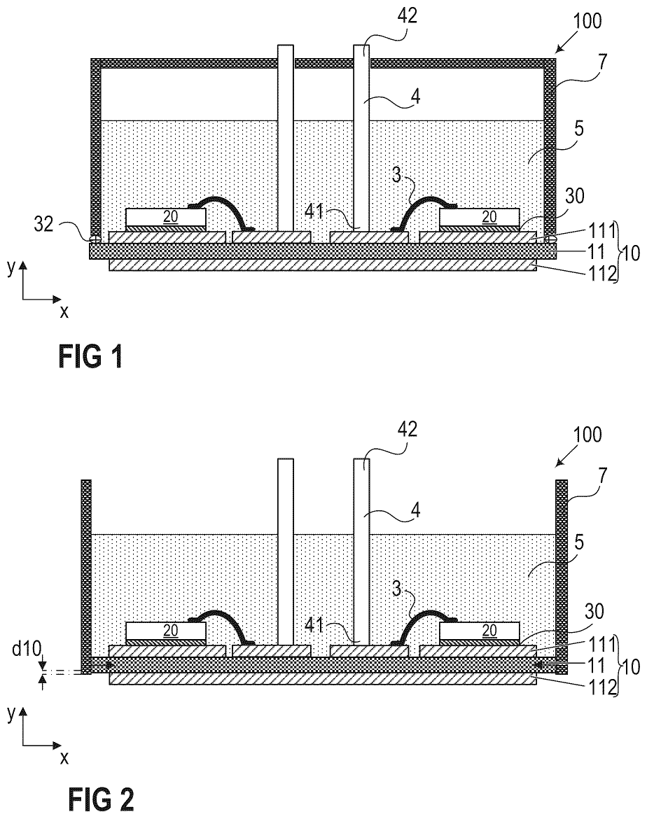

Referring to FIG. 1, a cross-sectional view of a semiconductor module 100 is illustrated. The semiconductor module 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 forms a base surface of the housing 7, while the housing 7 itself solely comprises sidewalls and a cover. In some power semiconductor module arrangements 100, more than one substrate 10 is arranged within the same housing 7.

One or more semiconductor bodies 20 may be arranged on the substrate 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes four different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The semiconductor module 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second end 42. The terminal elements 4 illustrated in FIG. 1, however, are only examples. Terminal elements 4 may be implemented in any other way and may be arranged at any other position. For example, one or more terminal elements 4 may be arranged close to or adjacent to the sidewalls of the housing 7. Any other suitable implementation is possible. The terminal elements 4 may consist of or include a metal such as copper, aluminum, gold, silver, or any alloys thereof, for example. The terminal elements 4 may be electrically and mechanically connected to the substrate 10 by an electrically conductive connection layer (not specifically illustrated for the terminal elements 4). Such an electrically conductive connection layer generally may be a solder layer, a layer of an electrically conductive adhesive, or a layer of a sintered metal powder, e.g., a sintered silver powder, for example. According to other examples, terminal elements 4 may be inserted into hollow sleeves which are attached to the substrate 10 (sleeves not specifically illustrated in FIG. 1).

Conventional semiconductor modules 100 generally further include an encapsulant or casting compound 5. The casting compound 5 may consist of or include a cured silicone gel or may be a rigid molding compound, for example. The casting compound 5 may at least partly fill the interior of the housing 7, thereby covering the components and electrical connections that are arranged on the substrate 10. The terminal elements 4 may be partly embedded in the casting compound 5. At least their second ends 42, however, are not covered by the casting compound 5 and protrude from the casting compound 5 through the housing 7, to the outside of the housing 7. The casting compound 5 is configured to protect the components and electrical connections inside the semiconductor module 100, in particular inside the housing 7, from certain environmental conditions and mechanical damage.

The housing 7 may be glued to the substrate 10 in order to remain in a desired position with respect to the substrate 10. A glued joint 32 (layer of glue) between the housing 7 and the substrate 10 is often sufficient to hold the housing 7 in its desired position with regard to the substrate 10. Gluing the housing 7 to the substrate 10, however, requires additional pretreatment steps (e.g., a plasma treatment of the substrate 10), a step in which the glue is applied to the substrate 10, as well as a hardening step in which the originally viscous glue is hardened, thereby attaching the housing 7 to the substrate 10. Each additional step during the assembly process requires additional process time and increases the overall cost of the power semiconductor module arrangement 100.

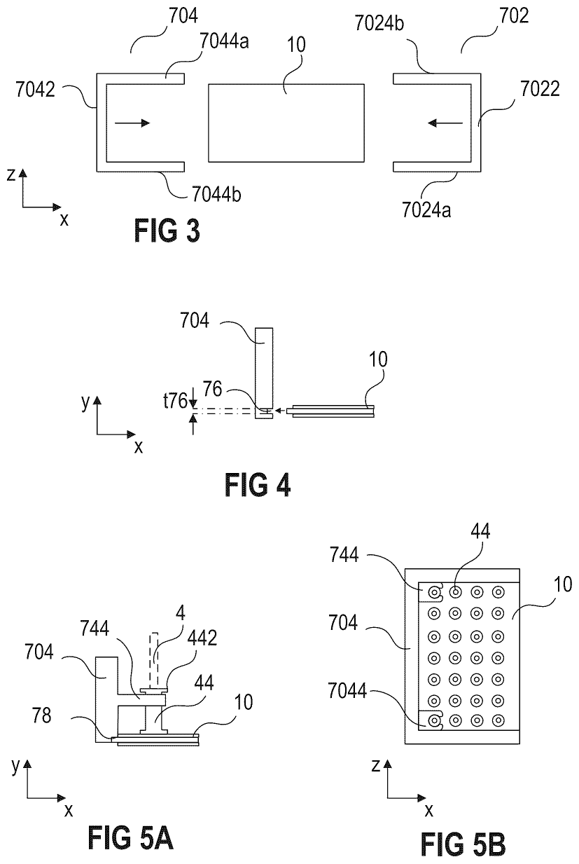

Now referring to FIG. 2, a cross-sectional view of a power semiconductor module arrangement 100 according to embodiments of the disclosure is schematically illustrated. The housing 7, instead of gluing it to the substrate 10, is arranged to surround and clamp the substrate 10 from all sides. That is, the housing 7 forms a closed frame around the substrate 10 and exerts pressure on at least some of a plurality of side surfaces of the substrate 10 along the circumference of the substrate 10. A top surface of the substrate 10 is a surface to which the semiconductor bodies 20 are mounted, and a bottom surface of the substrate 10 is a surface opposite the top surface and facing away from the semiconductor bodies 20. Side surfaces are surfaces of the substrate extending from the top surface to the bottom surface. While, in an assembled state of the housing 7 and the power semiconductor module arrangement 100, the housing 7 forms a closed frame around the substrate 10, in its unassembled state it comprises a first housing member 702 and a second housing member 704 which are separate and distinct from each other. This is schematically illustrated in the top view of FIG. 3.

During assembly of the housing 7, the housing 7 is arranged to surround the substrate 10. Arranging the housing 7 to surround the substrate 10 comprises moving the first housing member 702 and the second housing member 704 towards each other, with the substrate 10 arranged between the first housing member 702 and the second housing member 704. This is schematically illustrated by means of the arrows in FIG. 3. The substrate 10 is arranged between the first housing member 702 and the second housing member 704 such that a first side surface faces towards the first housing member 702 and a second side surface opposite the first side surface faces towards the second housing member 704. When the first housing member 702 and the second housing member 704 are in direct contact with each other, the first housing member 702 may be attached to the second housing member 704 such that the first and second housing members 702, 704 form a closed frame around the substrate 10 and exert pressure on at least some of the side surfaces of the substrate 10 along the circumference of the substrate 10.

In the example illustrated in FIG. 3, each of the first housing member 702 and the second housing member 704 comprises a base portion 7022, 7042, a first arm 7024a, 7044a extending from a first end of the respective base portion 7022, 7024, and a second arm 7024b, 7044b extending from a second end of the respective base portion 7022, 7042, wherein the first arm 7024a of the first housing member 702 is configured to be coupled to the second arm 7044b of the second housing member 704, and the second arm 7024b of the first housing member 702 is configured to be coupled to the first arm 7044a of the second housing member 704. That is, the first housing member 702 and the second housing member 704 in this example each are generally U-shaped. The base portions 7022, 7024 each form one of the side surfaces of the housing 7 in its assembled state. The first arm 7024a of the first housing member 702 together with the second arm 7044b of the second housing member 704, as well as the second arm 7024b of the first housing member 702 together with the first arm 7044a of the second housing member 704 form further side surfaces of the housing 7 in the assembled state. This, however, is only an example.

It is generally also possible, for example, that the first housing member 702 only comprises the base portion 7022, while the second housing member 704 comprises the base portion 7042, the first arm 7044a, and the second arm 7044b, wherein the first and second arms 7044a, 7044b of the second housing member 704 are configured to be directly coupled to the base portion 7022 of the first housing member 702. According to even further examples, each of the first housing member 702 and the second housing member 704 may comprise the respective base portion 7022, 7042 and the first arm 7024a, 7044a. That is, the first housing member 702 and the second housing member 704 may generally be L-shaped. The first arm 7024a of the first housing member 702 in this example may be configured to be directly coupled to the base portion 7042 of the second housing member 704. Similarly, the first arm 7044a of the second housing member 704 may be configured to be directly coupled to the base portion 7022 of the first housing member 702. Alternatively, any other suitable implementations are generally possible.

The closed frame formed by the first housing member 702 and the second housing member 704 comprises a mounting section for mounting the housing 7 to the substrate 10. This mounting section may be arranged at a defined distance d10 from a lower end of the first and second housing members 702, 704. The lower end of the first and second housing members 702, 704 is opposite an upper end of the first and second housing members 702, 704, wherein a lid or cover of the housing 7 may be attached to the upper end of the first and second housing members 702, 704, for example.

As the closed frame that is formed by the first housing member 702 and the second housing member 704 exerts a certain pressure on at least some of a plurality of side surfaces of the substrate 10 along the circumference of the substrate 10 (indicated by means of arrows in FIG. 2), the substrate 10 is held in a desired position with respect to the housing 7. The pressure that can be exerted on the substrate 10 by means of the housing 7, however, may be limited. That is, there is a risk that clamping the substrate 10 between the first housing member 702 and the second housing member 704 is not sufficient to permanently hold the substrate 10 in its desired position with respect to the housing 7.

The housing 7, therefore, may comprise a holding mechanism configured to prevent a substrate 10 arranged within the closed frame formed by the first housing member 702 and the second housing member 704 from shifting out if its desired position or even falling out of the housing 7. Such a holding mechanism may generally be implemented in any suitable way. Several possible examples of different holding mechanisms will be described in the following by means of FIGS. 4, 5A-5B and 6A-6B.

According to some examples, the holding mechanism comprises a groove extending along an inside of the closed frame formed by the first housing member 702 and the second housing member 704. In the example illustrated in FIG. 4, the groove is implemented as a channel 76. The channel 76 may have a thickness t76 in a vertical direction y that is similar to the dimensions (i.e. thickness) of a substrate 10 (e.g., thickness of dielectric insulation layer 11) in the same direction. The channel 76 may extend along at least one of the sidewalls of the housing 7 in the assembled state. According to one example, the channel 76 is a continuous channel extending around the entire inner circumference of the housing 7. The substrate 10 may slide into the channel 76 during assembly of the housing 7, as is indicated by means of an arrow in FIG. 4. In this way, the substrate 10 may be prevented from moving vertically, when the housing 7 is arranged to surround the substrate 10. The channel 76 prevents movements of the substrate 10 both in an upwards as well as a downwards direction.

The channel 76, however, is not necessarily required to continuously extend around the inner circumference of the housing 7 in its assembled state. According to other examples, the channel 76 may have two or more separate sections. For example, a first section may extend along a first sidewall of the housing 7 (e.g., along the base portion 7022 of the first housing member 702), and a second section may extend along a second sidewall of the housing 7 that is opposite the first sidewall (e.g., along the base portion 7042 of the second housing member 704). It may be sufficient that two opposite ends of the substrate 10 be arranged in different sections of the channel 76, for example, in order to hold the substrate 10 in its desired position.

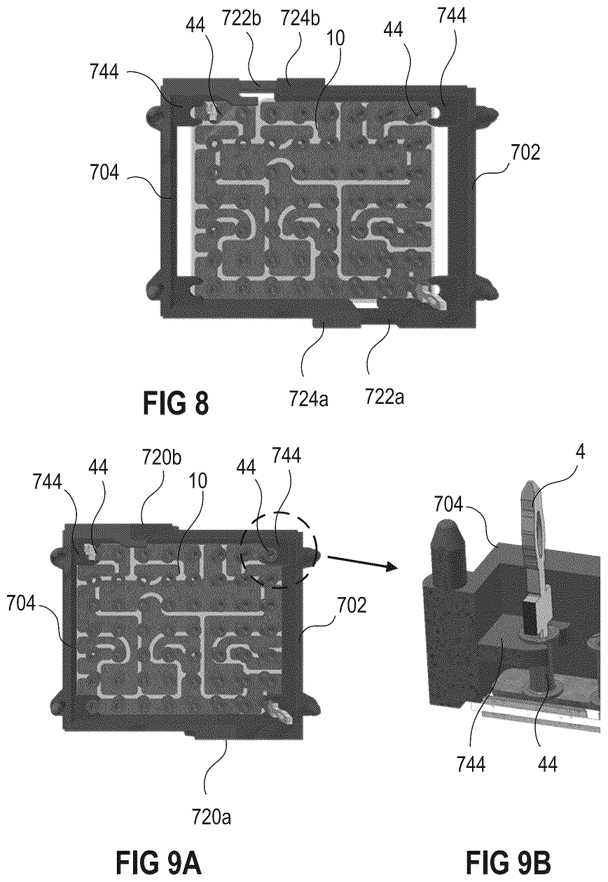

Now referring to FIGS. 5A and 5B, the holding mechanism, instead of or in addition to a groove, may comprise one or more gripping elements 744 attached to the first housing member 702 and/or the second housing member 704 and configured to engage with a corresponding counter element attached to the substrate 10. According to one example, the holding mechanism comprises four gripping elements 744, as is schematically illustrated in FIGS. 8 and 9A, for example. That is, one gripping element 744 may be arranged in each of the four corners of a rectangular or square semiconductor module 100, for example. It may, however, also be sufficient if the holding mechanism comprised of only two gripping elements 744 arranged on opposing sides of the housing 7, for example. Any other number of gripping elements 744 is generally possible. In some semiconductor modules, a single holding element 744 (exactly one) may be sufficient. The number of gripping elements 744 may depend on the size of the housing 7 and the size of the substrate 10 that is to be arranged in the housing 7. The larger the housing 7 and the substrate 10, the more gripping elements 744 may be required in order to prevent the substrate 10 from shifting out of its desired position, for example. If the gripping elements 744 are combined with other kinds of holding mechanisms (e.g., the channel 76 of FIG. 4), a smaller number of gripping elements 744 may be needed.

Each gripping element 744 may have a fork-like geometry, as is exemplarily illustrated in the top view of FIG. 5B, for example. Each gripping element 744 may be configured to clasp or engage with a corresponding counter element attached to the substrate 10. The counter element may be a dedicated component which has no other function than providing a counter element for the gripping element 744. It is, however, also possible that an element which has a different function in the power semiconductor module also functions as a counter element.

According to one example, the counter element comprises a sleeve 44 having a collar 442 formed at an end of the sleeve 44 that faces away from the substrate 10. The gripping element 744 with its fork-like geometry may be configured to clasp the sleeve 44 in a section directly adjacent to the collar 442 between the collar and the substrate 10 (see, e.g., FIG. 5A). The collar 442 may have a diameter that is larger than a diameter of the fork-like gripping element 744. In this way, the substrate 10 may be prevented from unintentionally sliding out of the housing 7, as the collar 442 will not be able to slide through the gripping element 744.

The sleeve 44, as has been described above, may be a dedicated element that merely functions as a counter element for the gripping element 744. Sleeves, however, are often used in semiconductor modules 100, e.g., for attaching terminal elements 4 to a substrate 10. A terminal element 4 inserted into the sleeve 44 is schematically illustrated in dashed lines in FIG. 5A. That is, a terminal element 4 may be inserted into a sleeve 44, the sleeve 44 providing a mechanical and electrical connection between the terminal element 4 and the substrate 10. Using a sleeve 44 or any other component that is already present on the substrate 10 for other reasons as a counter element has the advantage that no additional space is required on the substrate 10 for providing counter elements. The gripping elements 744 may be configured to clasp or engage with any other element that is present on the substrate 10 and that is suitable to be clasped instead of a sleeve 44. A connection between the one or more gripping elements 744 and the corresponding counter elements may be easily formed while attaching the first housing member 702 and the second housing member 704 to each other, with a substrate 10 with counter elements arranged thereon arranged in between.

In the example illustrated in FIG. 5A, the second housing member 704 comprises a groove which, instead of as a channel, is implemented as a depression 78 (or step) formed at a lower end of the second housing member 704. A depression 78 may be similarly formed at a lower end of the first housing member 702. The depression 78 prevents the substrate 10 from unintentionally sliding into the housing 7 in the vertical direction y. At the same time, pressure may be exerted on the respective side surface of the substrate 10 in a horizontal direction x that is perpendicular to the vertical direction y. In this way, the substrate 10 is securely held in its desired position and cannot move in a horizontal plane nor towards the inside of the housing 7 in the vertical y direction y.

The difference between the channel 76 as illustrated in FIG. 4 and the depression 78 as illustrated in FIG. 5A can be seen in that a channel 76 contacts the substrate 10 from above, from below, and from the side and, therefore, a movement of the substrate 10 in all directions in space can be prevented when the substrate 10 is arranged in its final mounting position within the housing 7. A depression 78 only contacts the substrate 10 from above and from the side. Therefore, a movement of the substrate 10 can be prevented in most, but not all directions in space. In particular, the depression 78 does not prevent the substrate 10 from moving out of the housing 7 in a vertical direction y.

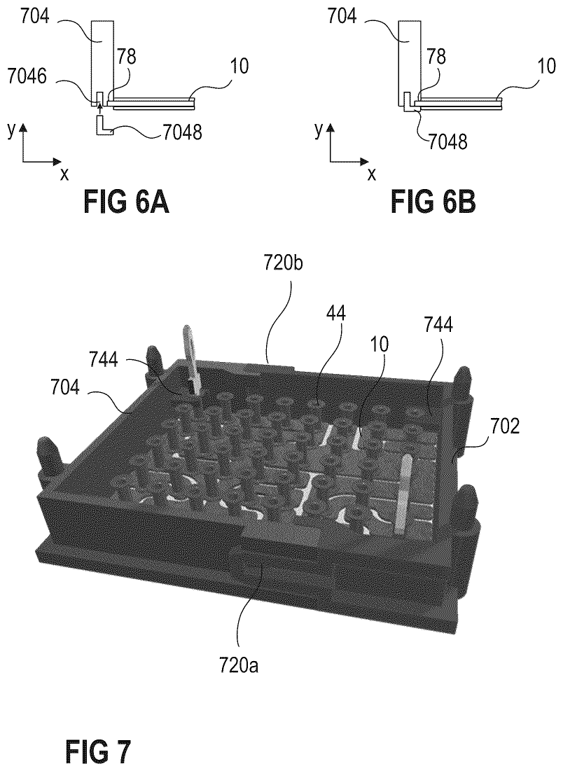

Now referring to FIGS. 6A and 6B, an even further example of a holding mechanism is schematically illustrated. In this example, the second housing member 704 (as well as the first housing member 702 which, however, is not explicitly illustrated in FIGS. 6A and 6B) comprises a depression 78, similar to what has been described with respect to FIGS. 5A-5B above. By means of the depression 78, the substrate 10 is prevented from unintentionally moving in a horizontal plane as well as in the vertical direction y towards the inside of the housing 7. In order to also prevent the substrate 10 from unintentionally sliding vertically out of the housing 7, the first housing member 702 and/or the second housing member 704 may further comprise one or more indentations 7046 extending vertically into the respective housing member from its bottom end. The holding mechanism in this example further comprises one or more plug-in elements 7048, each of the one or more plug-in elements 7048 comprising a first section configured to be inserted into one of the one or more indentations 7046, and a second section configured to press the substrate 10, which is arranged in the depression 78 and between the second section of the plug-in element 7048 and the housing 7, towards the housing 7. FIG. 6A illustrates the plug-in element 7048 in an unmounted state, and FIG. 6B illustrates the plug-in element 7048 in a mounted state. As can be seen, in the mounted state the plug-in element 7048 together with the depression 78 forms a channel, similar to what has been described with respect to FIG. 4 above. In the example illustrated in FIGS. 6A-6B, the plug-in element 7948 is generally L-shaped. A plug-in element 7048, however, may have any other suitable shape instead.

Generally, the first housing member 702 may be attached to the second housing member 704 in any suitable way. According to one example, the first housing member 702 may be attached to the second housing member 704 by means of a glued or a welded connection. Gluing or welding the housing members 702, 704 to each other, however, requires additional steps for forming the connection. According to another example, therefore, the first housing member 702 and the second housing member 704, in the assembled state of the housing 7, are attached to each other by means of a first snap-fit connection 720a and a second snap-fit connection 720b. This is schematically illustrated in FIGS. 7, 8 and 9A, for example. The first snap-fit connection 720a may comprise a first snap-joint 722a attached to or integrally formed with the first housing member 702, and a first mating component 724a attached to or integrally formed with the second housing member 704, wherein the first snap-joint 722a and the first mating component 724a are configured to engage with each other to form the first snap-fit connection 720a. The second snap-fit connection 720b may comprise a second snap-joint 722b attached to or integrally formed with the second housing member 704, and a second mating component 724b attached to or integrally formed with the first housing member 702, wherein the second snap-joint 722b and the second mating component 724b are configured to engage with each other to form the second snap-fit connection 720b.

As can be seen in FIG. 8, for example, the first snap-joint 722a may be attached to or integrally formed at an end of the first arm 7024a of the first housing member 702, and the first mating component 724a may be attached to or integrally formed at an end of the second arm 7044b of the second housing member 704. Similarly, the second snap-joint 722b may be attached to or integrally formed at an end of the first arm 7044a of the second housing member 704, and the second mating component 724b may be attached to or integrally formed at an end of the second arm 7024b of the first housing member 702. When the first housing member 702 and the second housing member 704 are moved towards each other during assembly of the power semiconductor module arrangement, the snap-joints 722a, 722b may easily engage with the respective mating components 724a, 724b. Snap-fit connections 720a, 720b are generally known and can be implemented in many different suitable ways. Most snap-fit connections generally have in common that they can be easily formed without much effort, but cannot be easily disengaged again. Some snap-fit connections are even permanent and cannot be disengaged without damaging the elements of the snap-fit connection. Most snap-fit connections, however, generally can be disengaged, but a certain amount of force is required to do so. If a snap-fit connection 720a, 720b that is used to attach the first housing member 702 and the second housing member 704 to each other is not deliberately opened, the probability of the snap-fit connection 720a, 720b unintentionally disengaging during the handling and normal operation of the power semiconductor module arrangement is generally towards zero.

FIG. 7 illustrates a three-dimensional view of a semiconductor module according to embodiments of the disclosure in a mounted state of the housing 7. Exemplary snap-fit connections 720a, 720b, are schematically illustrated in greater detail therein. As has been mentioned above, however, the snap-fit connections 720a, 720b can be implemented in any other suitable way and are not restricted to the specific geometry that is exemplarily illustrated in FIG. 7. FIG. 8 schematically illustrates a top view of the semiconductor module of FIG. 7 in an unmounted state. In the example illustrated in FIG. 8, the snap-fit connections 720a, 720b have not yet been formed. Even further, the gripping elements 744 are not yet engaged with the corresponding counter elements (sleeves 44) on the substrate 10. FIG. 9A schematically illustrates a top view of the arrangement of FIG. 7 in its final mounting position. FIG. 9B schematically illustrates in further detail in a three-dimensional cross-sectional view of a section of the semiconductor module a connection formed between a gripping element 744 and a corresponding counter element (i.e. sleeve 44) arranged on the substrate 10.

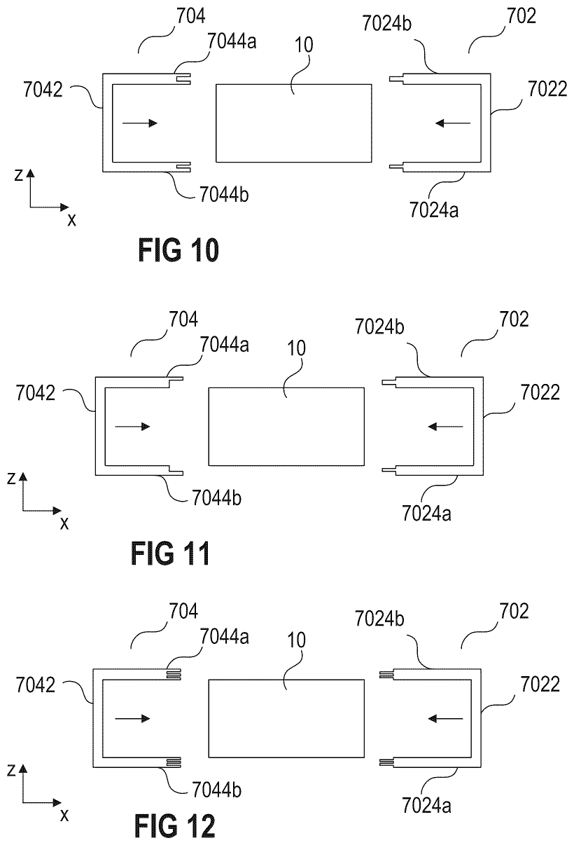

Now referring to FIGS. 10, 11, and 12, the snap-joints and mating components may have different shapes when seen from above. FIG. 10 schematically illustrates snap-fit connections which may be referred to as “labyrinth design”, for example. In this example, the snap-joints may have a fork like geometry, while the mating components may generally have the shape of a single finger, for example, which may engage with the fork-like snap-joints. In the example illustrated in FIG. 11, the snap-joints and the mating components all have the shape of a single finger, which may be referred to as “single overlap design”, for example. In the example illustrated in FIG. 12, on the other hand, the snap-joints and the mating components all have a fork-like geometry, which may be referred to as “multi-tooth design”, for example. In all examples, the first housing member 702 and the second housing member 704, in particular the snap-joints and corresponding mating components, overlap to a certain degree in their final mounting position. In the example illustrated in FIG. 12 (multi-tooth design), a creepage distance in the area of the snap-fit connections between the inside and the outside of the housing 7, due to the double fork-like geometry (multi-tooth design), is significantly longer as compared to the single overlap design of FIG. 11, for example. That is, a specific implementation of the snap-fit connections may be chosen based on requirements concerning creepage distances.

In the examples illustrated in FIGS. 10, 11, and 12, both snap-joints are attached to or integrally formed with the second housing member 704, and both mating components are attached to or integrally formed with the first housing member 702. This is generally possible. However, in these examples, the first housing member 702 and the second housing member 704 inevitably differ from each other. That is, during assembly of the housing 7, care must be taken that the correct elements, i.e. one first housing member 702 and one second housing member 704, are used. Even further, two different kinds of housing members need to be produced. That is, two different forms (e.g., molds) are required if, for example, the housing members 702, 704 are formed by means of molding methods. This can be avoided if the first housing member 702 and the second housing member 704 are identical to each other. The first housing member 702 and the second housing member 704 being identical to each other means that they have the same shape, the same dimensions, and are formed of the same material. In this way, the first housing member 702 may be readily replaced by a second housing member 704, and vice versa, resulting in the same housing 7. In other words, the identical first and second housing members 702 in the examples illustrated in FIGS. 7, 8, and 9A are rotationally symmetrical about an axis of rotation (axis of rotation not specifically illustrated in the figures).

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A housing for a semiconductor module, the housing comprising:
a first housing member; and
a second housing member,
wherein in an unmounted state of the housing, the first housing member and the second housing member are separate and distinct from each other,
wherein in an assembled state of the housing, the first housing member and the second housing member are attached to each other and together form a closed frame, and
wherein the closed frame formed by the first housing member and the second housing member comprises a mounting section for mounting the housing to a substrate such that the closed frame extends around the substrate.

2. The housing of claim 1, wherein each of the first housing member and the second housing member comprises:
a base portion;
a first arm extending from a first end of the respective base portion; and
a second arm extending from a second end of the respective base portion,
wherein the first arm of the first housing member is configured to be coupled to the second arm of the second housing member, and
wherein the second arm of the first housing member is configured to be coupled to the first arm of the second housing member.

3. The housing of claim 1, further comprising:
a holding mechanism configured to prevent a substrate arranged within the closed frame formed by the first housing member and the second housing member from falling out of the housing.

4. The housing of claim 3, wherein the holding mechanism comprises a groove extending along an inside of the closed frame formed by the first housing member and the second housing member.

5. The housing of claim 4, wherein the groove comprises a channel or a depression.

6. The housing of claim 3, wherein the holding mechanism comprises one or more gripping elements attached to the first housing member and/or the second housing member and configured to engage with a corresponding counter element attached to the substrate.

7. The housing of claim 6, wherein the counter element comprises a sleeve having a collar formed at an end of the sleeve facing away from the substrate, and wherein the gripping element comprises a fork-like geometry and is configured to clasp the sleeve in a section directly adjacent to the collar between the collar and the substrate.

8. The housing of claim 3, wherein the first housing member and/or the second housing member comprise one or more indentations and the holding mechanism comprises one or more plug-in elements, and wherein each of the one or more plug-in elements comprises a first section configured to be inserted into one of the one or more indentations and a second section configured to press a substrate arranged between the second section and the respective housing member towards the housing.

9. The housing of claim 1, wherein the first housing member and the second housing member, in the assembled state of the housing, are attached to each other by a first snap-fit connection and a second snap-fit connection.

10. The housing of claim 9, wherein:
the first snap-fit connection comprises a first snap-joint attached to or integrally formed with the first housing member and a first mating component attached to or integrally formed with the second housing member, the first snap-joint and the first mating component being configured to engage with each other to form the first snap-fit connection; and
the second snap-fit connection comprises a second snap-joint attached to or integrally formed with the second housing member and a second mating component attached to or integrally formed with the first housing member, the second snap-joint and the second mating component being configured to engage with each other to form the second snap-fit-connection.

11. The housing of claim 1, wherein the first housing member and the second housing member are identical to each other.

12. A semiconductor module, comprising:
a substrate; and
a housing comprising a first housing member and a second housing member attached to each other and together forming a closed frame,
wherein the closed frame formed by the first housing member and the second housing member comprises a mounting section that mounts the housing to the substrate such that the closed frame extends around the substrate,
wherein the closed frame exerts pressure on at least some of a plurality of side surfaces of the substrate along a circumference of the substrate.

13. A method for assembling a semiconductor module, the method comprising
arranging a housing to surround a substrate, the housing comprising a first housing member and a second housing member,
wherein arranging the housing to surround the substrate comprises:
moving the first housing member and the second housing member towards each other, with the substrate arranged between the first housing member and the second housing member; and
attaching the first housing member to the second housing member such that the first and second housing members together form a closed frame around the substrate and exert pressure on at least some of a plurality of side surfaces of the substrate along the circumference of the substrate.
